(19) United States
(12) Patent Application Publication
(10) Pub. No.: US 2009/0292971 A1
(43) Pub. Date: Nov. 26, 2009

(54) Data recovery techniques

(76) Inventors: Chun Fung Man, Vancouver (CA); Jonathan Schmidt, Vancouver (CA); Scott Nelson, Vancouver (CA)

Correspondence Address: INTEL CORPORATION;c/o CPA Global, P.O. BOX 52050, MINNEAPOLIS, MN, 55402, US

(21) Appl. No.: 12/288,617

(22) Filed: Oct. 22, 2008

Related U.S. Application Data
(60) Provisional application No. 61/128,468, filed on May 21, 2008.
(60) Provisional application No. 61/128,677, filed on May 23, 2008.

(51) Int. Cl. G11C 29/04; G06F 11/07

(52) U.S. Cl. 714/763; 714/E11.022

(57) ABSTRACT

Techniques are described that include reading a portion of a memory and determining whether there is any uncorrectable codeword. Due to time varying errors present during a read operation, the uncorrectable codeword may become read as a correctable codeword at another time. If any uncorrectable codeword is present in the portion, the portion can be re-read to determine whether any uncorrectable codeword is instead correctable. Prior to re-reading the portion, a reference level used to determine whether a logic zero or one is stored can be adjusted. Adjusting the reference level can allow an uncorrectable codeword to become a correctable codeword.

### RELATED APPLICATIONS

This application is related to U.S. provisional application Ser. No. 61/128,468, filed May 21, 2008, and claims priority to that date for all applicable subject matter. This application is also related to U.S. provisional application Ser. No. 61/128,677, filed May 23, 2008, and claims priority to that date for all applicable subject matter.

### FIELD

The subject matter disclosed herein relates generally to techniques to read information from a storage medium.

### RELATED ART

Some types of non-volatile memory, such as flash memory, record binary data by storing a certain amount of charge in a memory cell. When the data is read, the voltage level of the stored charge is compared to one or more reference voltage levels. The binary value of the bit read from that cell will depend on whether the voltage of the stored charge is higher or lower than the reference voltage. However, since the stored charge is an analog phenomenon, its actual value may not be exactly what was intended, and it may even leak away over time, so this type of non-volatile memory is subject to errors when reading the data stored in the memory. When such errors occur while reading sequential data from the memory, an error checking and correction (ECC) process may be used to detect and potentially correct the errors. But some errors may even be uncorrectable with the ECC. Whether a particular error is correctable at the time or not, this degradation in the reliability of the memory is an ongoing problem. This type of problem may become even more widespread as flash memories move increasingly to smaller geometries and to multi-level cell structures, which have less tolerance for variation in the stored charge.

Some memory devices use a triple verify technique during a program verify operation to cancel random noise effects. The triple verify technique involves multiple reads (or verifies) of a memory segment. The triple verify technique relies on majority vote logic to decide the result of each bit.

When errors are detected in content read from memory, some devices read the content from memory again. However, the content is read without changing parameters used to evaluate the content in memory.

### BRIEF DESCRIPTION OF THE DRAWINGS

Embodiments of the present invention are illustrated by way of example, and not by way of limitation, in the drawings and in which like reference numerals refer to similar elements.

FIGS. 1-3 depict systems in accordance with various embodiments of the present invention.

FIG. 4 depicts an example of a read and two re-reads of a portion of memory, in accordance with an embodiment.

FIG. 5 depicts an example of adjusting reference levels prior to re-reading of a portion of memory, in accordance with an embodiment.

FIG. 6 depicts a process that can be used to read a memory, in accordance with an embodiment.

### DETAILED DESCRIPTION

Reference throughout this specification to “one embodiment” or “an embodiment” means that a particular feature, structure, or characteristic described in connection with the embodiment is included in at least one embodiment of the present invention. Thus, the appearances of the phrase “in one embodiment” or “an embodiment” in various places throughout this specification are not necessarily all referring to the same embodiment. Furthermore, the particular features, structures, or characteristics may be combined in one or more embodiments.

In the following description and claims, the terms “coupled” and “connected,” along with their derivatives, may be used. It should be understood that these terms are not intended as synonyms for each other. Rather, in particular embodiments, “connected” is used to indicate that two or more elements are in direct physical or electrical contact with each other. “Coupled” is used to indicate that two or more elements co-operate or interact with each other, but they may or may not be in direct physical or electrical contact.

As used in the claims, unless otherwise specified the use of the ordinal adjectives “first”, “second”, “third”, etc., to describe a common element, merely indicate that different instances of like elements are being referred to, and are not intended to imply that the elements so described must be in a given sequence, either temporally, spatially, in ranking, or in any other manner.

Various embodiments include reading a portion of a memory and determining whether there are any uncorrectable codewords, i.e., codewords with more errors than an ECC code is capable of correcting. Due to time varying errors present during a read operation, uncorrectable codewords may become readable as codewords with correctable errors at another time. If any uncorrectable codewords are present in the portion, the portion can be re-read to determine whether the uncorrectable codewords are instead correctable codewords, i.e., codewords with errors that are correctable using at least an ECC code. Prior to re-reading the portion, one or more reference levels used to determine whether a logic zero or one is stored can be adjusted. Adjusting the reference level can allow an uncorrectable codeword to become a correctable codeword.

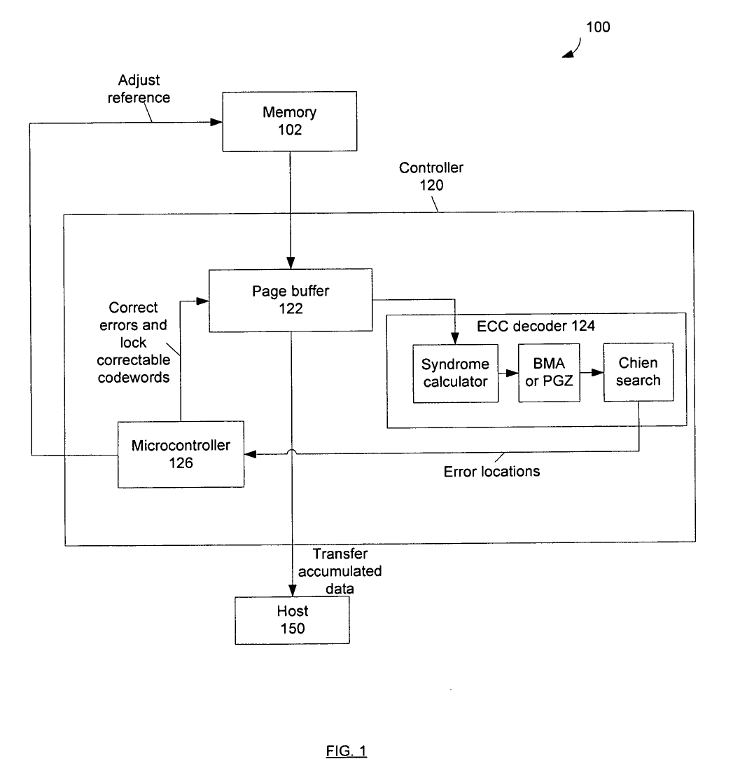

FIG. 1 depicts a system 100 in accordance with an embodiment of the present invention. System 100 includes a memory 102, memory controller 120, and host 150.

Host 150 may request retrieval of contents of memory 102. Host 150 may include a display device and a network interface (both not depicted). For example, a host may be included in any of a cell phone, personal digital assistant, digital camera, music player, blade server, or any other electronic device.

Memory 102 may employ any feasible type of non-volatile storage technology that uses an adjustable reference voltage for read operations. For example, memory 102 may be implemented as a NAND memory device. Reads of an entire range of sequential memory locations in memory 102 may be accomplished using a single read command (such as but not limited to reading a page of memory from a NAND flash memory array), rather than reading an individual byte or word with a single read command.

Memory controller 120 may include a page buffer 122, ECC decoder 124, and microcontroller 126. Page buffer 122 may store a page of data received from memory 102. In response to instructions from microcontroller 126, page buffer 122 may have the capability to prevent specified codewords from being overwritten.

ECC decoder 124 may perform error checking and correction (ECC) to detect and correct errors in codewords stored in page buffer 122. For example, for each codeword, ECC decoder 124 may perform syndrome calculation, Berlekamp-Massey algorithm (BMA) or Peterson-Gorenstein-Zierler (PGZ), and Chien search operations to detect and correct errors. In addition, or alternatively, ECC decoder 124 may use other calculations. ECC decoder 124 may identify to microcontroller 126 each uncorrectable codeword. In one example, an uncorrectable codeword includes more than 14 bit errors for a 516 byte codeword.

Microcontroller 126 may correct bit errors in correctable codewords stored in page buffer 122 and identify correctable codewords in page buffer 122 that are not to be overwritten in subsequent re-reads of the same page in memory 102. Microcontroller 126 may request re-read of a page from memory 102 when the page includes at least one uncorrectable codeword. In some cases, microcontroller 126 may request re-read if a threshold number of uncorrectable codewords are detected, where the threshold number is greater than one. Microcontroller 126 may request re-reads of the page until all codewords have been corrected at least once or a re-read iteration limit is reached. Re-reads of a page do not overwrite codewords in page buffer 122 that are locked by microcontroller 126. Microcontroller 126 may cause transfer of the contents of page buffer 122 to host 150 after all codewords have been corrected at least once or a re-read iteration limit is reached.

Memory 102 may be affected by time varying errors from a variety of noise sources. Some of these noise sources, such as thermal noise and Random Telegraph Signal (RTS) noise, are random phenomena which vary from one read to the next. Accordingly, re-reading a page may result in a once uncorrectable codeword becoming correctable.

In some cases, for a re-read, microcontroller 126 may request adjustment of one or more reference voltages applied to read a page in memory 102. At least two manners of adjusting the reference voltage can be used. In various embodiments, the reference voltage used for read operations in memory 102 may be adjusted up or down, based on the type of errors detected over a range of addresses (e.g., a page, but other ranges may be used). In this scheme, the number of errors in one direction may be compared to the number of errors in the other direction (for example, the number of 0-to-1 errors may be compared to the number of 1-to-0 errors). If there are no more errors in one direction than the other, then the causes of these errors are assumed to be random and no adjustment to the reference voltage is made to correct it. But if the accumulated total indicates more errors in one direction than the other (beyond a given threshold), the reference voltage may be adjusted in an attempt to make that difference closer to zero for subsequent reads. For multi-level cells, where there are multiple reference voltages for each cell, each reference voltage may be adjusted separately by keeping track of the errors related to that particular reference voltage.

In various embodiments, the reference voltage used for read operations in memory 102 may be adjusted up or down in an attempt to read data from an area that previously produced an uncorrectable error. An uncorrectable error includes errors that are not correctable by the ECC scheme, even if the correct data may be obtained subsequently in other ways. The direction and amount of this adjustment may be based on the direction and net quantity of correctable errors within an address range. The ‘direction’ of an error pertains to whether the voltage in the data cell was higher than the reference voltage when it should have been lower, or lower than the reference value when it should have been higher. The ‘net quantity’ of errors pertains to the difference between the total number of errors in one direction and the total number of errors in the other direction. The ‘address range’ pertains to a range of sequential addresses (e.g., all the sectors in a page).

There are several sources of noise in memory. Some are incurred at program time, and some are incurred at read time. Simple re-read techniques may be able to cancel out noise sources that occur at read time, but they may not affect program time noise effects. However, by changing a read parameter for the re-read, it is possible to cancel out program time noise effects. Adjusting the read reference voltages from one read to the next may reduce the raw bit error rate (RBER). In the course of moving the references voltages, the error rate for a particular codeword may increase or decrease. Codewords within the same page are not necessarily affected in the same way. When the read reference is moved, the number of bit errors on one codeword may decrease, but the number of raw bit errors on another codeword in the same page may increase.

In other embodiments, a parameter changed prior to a re-read may be at least timing parameters, bit-line bias voltage, or memory temperature. For example, adjustments can be made to trim registers that change the internal timing of a read of memory 102. Parameters such as the word line voltage charge time and the bit line voltage charge time could be changed.

For pages where large numbers of raw bit errors occur, it is possible that each individual ECC codeword can be decoded correctly for a particular read reference setting, but there is not a single read reference setting that allows all codewords in the page to be corrected. This situation may occur randomly, but more likely it is caused by physical variations in the flash cells across the array.

For ease of access, codewords are normally stored in contiguous blocks within a page. These contiguous address locations correspond to physically adjacent memory cells. For example, in one scenario, physically close cells are expected to behave similarly and there may be more variation between cells that are physically far apart in the array. For example, one part of the array might have a higher rate of charge loss, causing the cells in that region to lose charge faster. The codeword in that region of the array may be read with lower read reference values than for the codeword that contains cells in a region of slower charge loss.

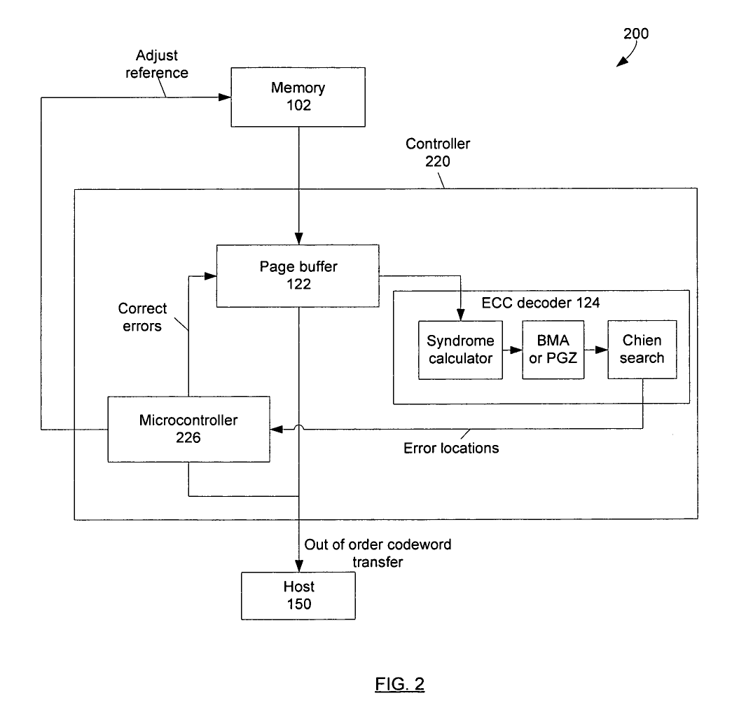

FIG. 2 depicts an example system 200 that potentially transfers correctable codewords to a host out-of-order in accordance with an embodiment. Controller 220 is substantially similar to controller 120 except that microcontroller 226 transfers corrected codewords to host 150 after correction of errors. Microcontroller 226 may request re-read of a page when one or more codeword is determined to be uncorrectable or until a re-read iteration is met. Prior to overwriting of page buffer 122 with a re-read, microcontroller 226 may request out of order transfer of correctable codewords to host 150. Once a successfully corrected codeword is transferred to the host, that codeword may not be transferred again to the host and/or re-read from the page in memory 102.

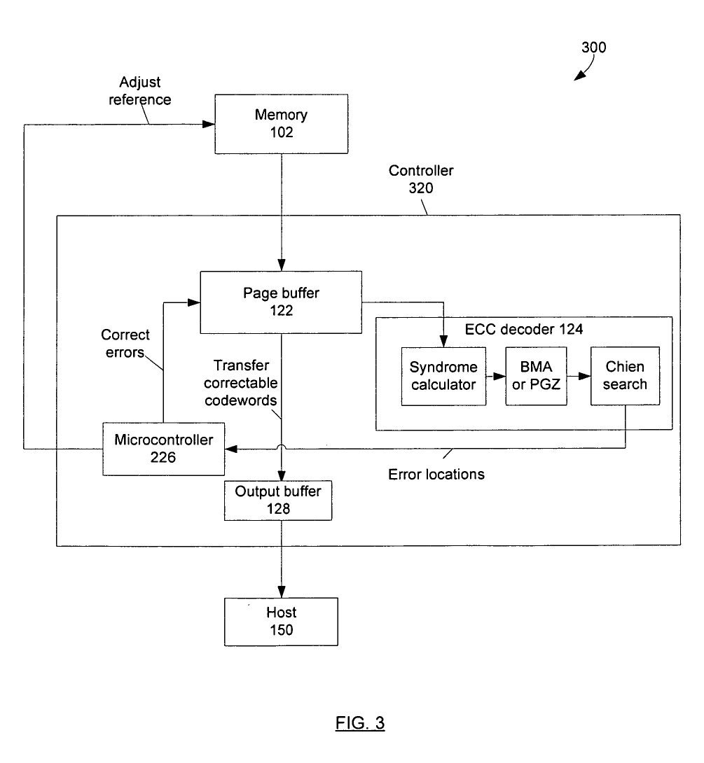

FIG. 3 depicts an example system that includes an output buffer used to store codewords prior to transfer to a host in accordance with an embodiment. Controller 320 is substantially similar to controller 120 except that an output buffer 128 stores correctable codewords and page buffer 122 may be overwritten in a subsequent re-read of a page from memory 102. Corrected or correctable codewords may be transferred from output buffer 128 to host 150 after a page in memory 102 has been re-read up to a prescribed number of times.

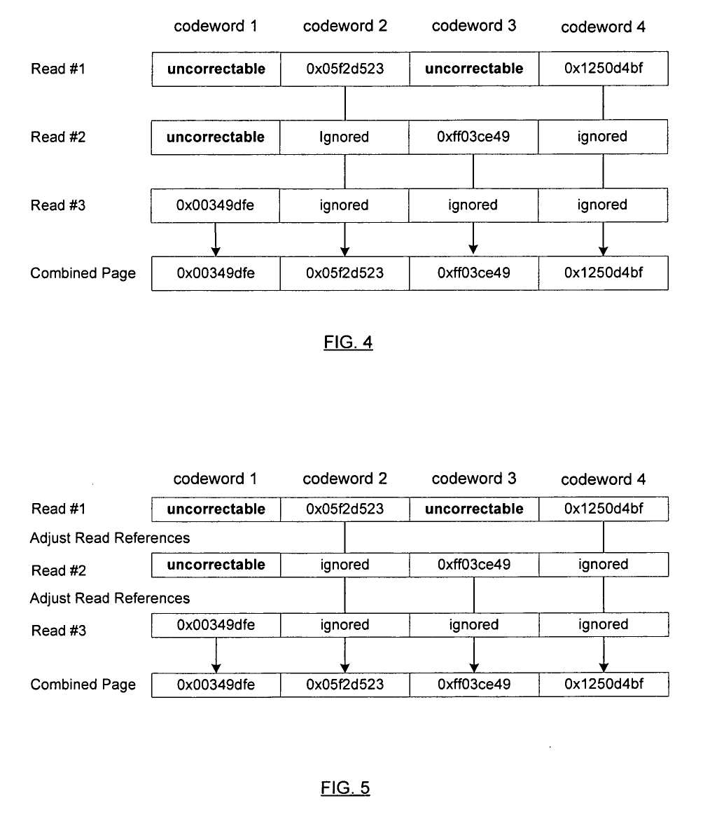

FIG. 4 depicts an example of a read and two re-reads of a portion of memory, in accordance with an embodiment. In this example, data from multiple reads are combined to form a fully corrected page. In this example, there are four codewords, codewords 1-4. During a first read of a memory segment, codewords 1 and 3 are uncorrectable and codewords 2 and 4 either include correctable errors or no errors.

During a second read of the memory segment, codewords 2 and 4 are ignored because they were previously accepted. Codeword 3 either includes correctable errors or no errors. Codeword 1, however, still is uncorrectable.

During a third read operation, codewords 2-4 are ignored because they were previously accepted. Codeword 1 is correctable. In the example of FIG. 4, the failing and uncorrected codewords from reads 1, 2 and 3 are not reported to the user. The user receives only the fully corrected codewords which form a complete error free page. The final page reported to the requester of the information contains correctable codewords from three different read operations. After three read operations, codewords 1-4 from multiple reads are combined to form a fully correctable segment and can be transmitted to the requester of the data.

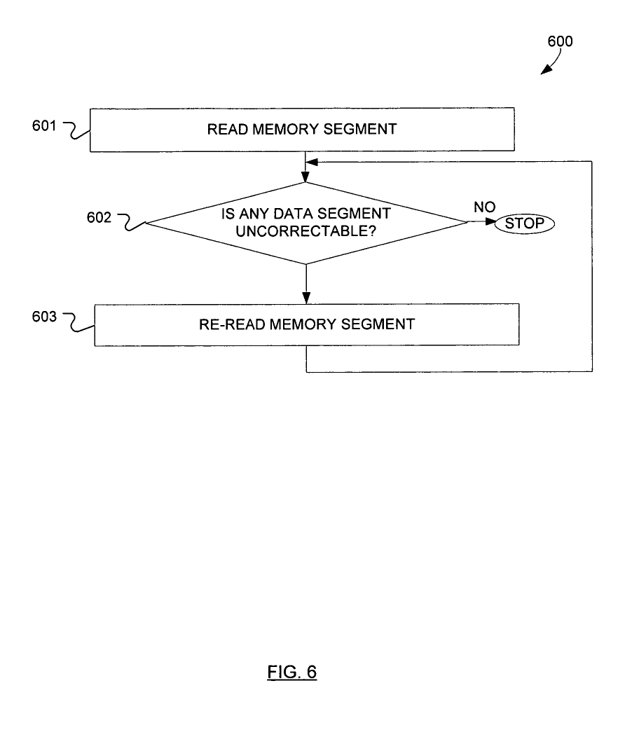

FIG. 5 depicts an example of adjusting reference levels prior to re-reading of a portion of memory, in accordance with an embodiment. The example of FIG. 5 is similar to that of FIG. 4 except that a reference voltage for a page in memory is adjusted prior to each re-read at least according to either manner described with regard to FIG. 1.

FIG. 6 depicts a process 600 that can be used to read a memory, in accordance with an embodiment. Block 601 may include reading a segment of memory. For example, the segment may be a page of memory.

Block 602 may include determining whether any data segment in the segment of memory is uncorrectable. For example, block 602 may include determining whether any codeword in the page of memory includes too many bit errors. In this example, a 516 byte codeword that includes more than 14 bit errors is considered uncorrectable. If any codeword is uncorrectable, block 603 may follow block 602. If all codewords are correctable, process 600 may end.

Block 603 may include re-reading the memory segment. In some embodiments, block 603 may include adjusting the reference voltage in a manner described with regard to FIG. 1 prior to re-reading the memory segment. Block 602 may follow block 603.

Embodiments of the present invention may be provided, for example, as a computer program product which may include one or more machine-readable media having stored thereon machine-executable instructions that, when executed by one or more machines such as a computer, network of computers, or other electronic devices, may result in the one or more machines carrying out operations in accordance with embodiments of the present invention. A machine-readable medium may include, but is not limited to, floppy diskettes, optical disks, CD-ROMs (Compact Disc-Read Only Memories), and magneto-optical disks, ROMs (Read Only Memories), RAMs (Random Access Memories), EPROMs (Erasable Programmable Read Only Memories), EEPROMs (Electrically Erasable Programmable Read Only Memories), magnetic or optical cards, flash memory, or other type of media/machine-readable medium suitable for storing machine-executable instructions.

The drawings and the forgoing description gave examples of the present invention. Although depicted as a number of disparate functional items, those skilled in the art will appreciate that one or more of such elements may well be combined into single functional elements. Alternatively, certain elements may be split into multiple functional elements. Elements from one embodiment may be added to another embodiment. For example, orders of processes described herein may be changed and are not limited to the manner described herein. Moreover, the actions of any flow diagram need not be implemented in the order shown; nor do all of the acts necessarily need to be performed. Also, those acts that are not dependent on other acts may be performed in parallel with the other acts. The scope of the present invention, however, is by no means limited by these specific examples. Numerous variations, whether explicitly given in the specification or not, such as differences in structure, dimension, and use of material, are possible. The scope of the invention is at least as broad as given by the following claims.

What is claimed is:

1. A method comprising:
reading data from a memory segment;
determining whether any portion of the data includes an uncorrectable codeword; and
selectively re-reading the memory segment in response to the portion of the data including the uncorrectable codeword, wherein the re-reading comprises adjusting at least one parameter used to evaluate contents of the memory segment.

2. The method of claim 1, wherein the determining comprises:
applying an error checking and correction process on the data to detect that a codeword includes an excessive number of errors.

3. The method of claim 1, wherein the selectively re-reading comprises selectively re-reading the memory segment until a determination that there is no uncorrectable codeword in the memory segment.

4. The method of claim 1, further comprising:
storing the data in a buffer; and
disabling overwrite of any portion of the data in the buffer determined to contain any correctable codeword.

5. The method of claim 1, further comprising:
storing the data in a buffer;
transferring any correctable codeword to a requester of the memory segment; and
allowing the buffer to be overwritten.

6. The method of claim 1, further comprising:
storing the data in a first buffer;
storing any correctable codeword from the data to a second buffer; and
allowing the first buffer to be overwritten.

7. The method of claim 1, wherein the adjusting at least one parameter used to evaluate contents of the memory segment comprises adjusting a reference voltage level applied to determine contents of the memory segment.

8. The method of claim 7, wherein adjusting a reference voltage level applied to determine contents of the memory segment comprises:
performing error checking and correction on the data to identify multiple correctable errors;
separating the errors into a first quantity of increasing value errors and a second quantity of decreasing value errors;
comparing the first quantity with the second quantity;
determining an amount and direction of a correction to a reference voltage, based on a result of said comparing; and
performing the correction to the reference voltage level wherein the performing the correction comprises changing the reference voltage level by an amount dependent on the result.

9. The method of claim 7, wherein adjusting a reference voltage level applied to determine contents of the memory segment comprises:
performing an error checking and correction process on the data;
determining that at least one of the units contains an uncorrectable error;
determining a direction and net quantity of correctable errors for each unit not containing an uncorrectable error but containing at least one correctable error; and
adjusting the reference voltage level by an amount based on the determining the direction and the net quantity.

10. An apparatus comprising:
a memory, the memory comprising a memory controller to control reading a memory array, wherein the controller is to:
read data from a memory segment;
determine whether any portion of the data includes an uncorrectable codeword; and
selectively re-read the memory segment in response to the portion of the data including an uncorrectable codeword, wherein to re-read the memory segment, the controller is to adjust at least one parameter used to evaluate contents of the memory segment.

11. The apparatus of claim 10, wherein the controller is also to:
store the data in a buffer; and
disable overwrite of any portion of the data in the buffer determined that contains a correctable codeword.

12. The apparatus of claim 10, wherein the controller is also to:
store the data in a buffer;
transfer any correctable codeword in the data to a requester of the memory segment; and
allow the buffer to be overwritten.

13. The apparatus of claim 10, wherein the controller is also to:
store the data in a first buffer;
store any correctable codeword from the data to a second buffer; and
allowing the first buffer to be overwritten.

14. The apparatus of claim 10, wherein to adjust at least one parameter used to evaluate contents of the memory segment, the controller is to adjust a reference voltage level applied to determine contents of the memory segment.

15. The apparatus of claim 14, wherein to adjust a reference voltage level applied to determine contents of the memory segment, the controller is to:
perform error checking and correction on the data to identify multiple correctable errors;
separate the errors into a first quantity of increasing value errors and a second quantity of decreasing value errors;
compare the first quantity with the second quantity;
determine an amount and direction of a correction to a reference voltage, based on a result of said comparing; and
perform the correction to the reference voltage level wherein to perform the correction, the controller is to change the reference voltage level by an amount dependent on the result.

16. The apparatus of claim 14, wherein to adjust a reference voltage level applied to determine contents of the memory segment, the controller is to:
perform an error checking and correction process on the data;
determine that at least one of the units contains an uncorrectable error;
determine a direction and net quantity of correctable errors for each unit not containing an uncorrectable error but containing at least one correctable error; and
adjust the reference voltage level by an amount based on the determining the direction and the net quantity.

17. A system comprising:
a display device;
a host computer communicatively coupled to the display device, wherein the host computer comprises a memory and wherein the host computer is to:
read data from a memory segment in the memory;
determine whether any portion of the data includes an uncorrectable codeword; and
selectively re-read the memory segment in response to the portion of the data including the uncorrectable codeword, wherein to re-read the memory segment, the controller is to adjust at least one parameter used to evaluate contents of the memory segment.

18. The system of claim 17, wherein the controller is also to:
store the data in a buffer; and
disable overwrite of any correctable codeword in the buffer.

19. The system of claim 17, wherein the controller is also to:
store the data in a buffer;
transfer any correctable codeword to a requester of the memory segment; and
allow the buffer to be overwritten.

20. The system of claim 17, wherein the controller is also to:
store the data in a first buffer;
store any correctable codeword from the data to a second buffer; and
allow the first buffer to be overwritten.

21. The system of claim 17, wherein to adjust at least one parameter used to evaluate contents of the memory segment, the controller is to adjust a reference voltage level applied to determine contents of the memory segment.
